(19) United States
(12) Patent Application Publication
(10) Pub. No.: US 2011/0127156 A1
(43) Pub. Date: Jun. 2, 2011

(54) CHAMBER FOR PROCESSING HARD DISK DRIVE SUBSTRATES

(75) Inventors: Majeed A. Foad, Sunnyvale, CA (US); Martin A. Hilkene, Gilroy, CA (US); Peter I. Porshnev, Santa Clara, CA (US); Jose Antonio Marin, San Jose, CA (US); Matthew D. Scotney-Castle, Morgan Hill, CA (US)

(73) Assignee: APPLIED MATERIALS, INC., Santa Clara, CA (US)

(21) Appl. No.: 12/955,619

(22) Filed: Nov. 29, 2010

Related U.S. Application Data
(60) Provisional application No. 61/265,263, filed on Nov. 30, 2009.

(51) Int. Cl. C23C 14/34

(52) U.S. Cl. 204/192.12; 204/298.07

(57) ABSTRACT

An apparatus for forming a magnetic pattern in a magnetic storage substrate. A chamber comprises a chamber wall that defines an internal volume, a substrate support in the internal volume of the chamber, a gas distributor disposed in a wall region of the chamber facing the substrate support, a compact energy source for ionizing a portion of the process gas provided to the chamber, and a throttle valve having a z-actuated gate member with a sealing surface for covering an outlet portal of the chamber. Ions are accelerated toward the substrate support by an electrical bias, amplifying the ion density of the process gas. A substrate disposed on the substrate support is bombarded by the ions to alter a magnetic property of the substrate surface.

### CROSS-REFERENCE TO RELATED APPLICATIONS

This application claims benefit of United States provisional patent application serial number 61/265,263, filed Nov. 30, 2009, which is herein incorporated by reference.

### FIELD

Embodiments of the invention generally relate to fabricating magnetic media such as hard-disk drive media and MRAM substrates. More specifically, embodiments of the invention relate to methods and apparatus for forming a patterned magnetic medium on a substrate.

### BACKGROUND

Magnetic media are used in various electronic devices such as hard disk drives and magnetoresistive random access memory (MRAM) devices. Hard-disk drives are the storage medium of choice for computers and related devices. They are found in most desktop and laptop computers, and may also be found in a number of consumer electronic devices, such as media recorders and players, and instruments for collecting and recording data. Hard-disk drives are also deployed in arrays for network storage. MRAM devices are used in various non-volatile memory devices, such as flash drives and dynamic random access memory (DRAM) devices.

Magnetic media devices store and retrieve information using magnetic fields. The disk in a hard-disk drive is configured with magnetic domains that are separately addressable by a magnetic head. The magnetic head moves into proximity with a magnetic domain and alters the magnetic properties of the domain to record information. To recover the recorded information, the magnetic head moves into proximity with the domain and detects the magnetic properties of the domain. The magnetic properties of the domain are generally interpreted as corresponding to one of two possible states, the “0” state and the “1” state. In this way, digital information may be recorded on the magnetic medium and recovered thereafter.

Magnetic storage media generally comprise a glass, composite glass/ceramic, or metal substrate, which is generally non-magnetic, with a magnetically susceptible material between about 100 nm and about 1 μm thick deposited thereon by a PVD or CVD process. In one embodiment, a layer comprising cobalt and platinum is sputter deposited on a structural substrate to form a magnetically active layer. The magnetically susceptible layer is generally either deposited to form a pattern or patterned after deposition, such that the surface of the device has areas of magnetic susceptibility interspersed with areas of magnetic inactivity. By one method, the non-magnetic substrate is topographically patterned, and the magnetically susceptible material deposited by spin-coating or electroplating. The disk may then be polished or planarized to expose the non-magnetic boundaries around the magnetic domains. In some cases, the magnetic material is deposited in a patterned way to form magnetic grains or dots separated by a non-magnetic area.

Such methods are expected to yield storage structures capable of supporting data density up to about 1 TB/in², with individual domains having dimensions as small as 20 nm. Where domains with different spin orientations meet, there is a region referred to as a Bloch wall in which the spin orientation goes through a transition from the first orientation to the second. The width of this transition region limits the areal density of information storage because the Bloch wall occupies an increasing portion of the total magnetic domain.

To overcome the limit due to Bloch wall width in continuous magnetic thin films, the domains can be physically separated by a non-magnetic region (which can be narrower than the width of a Bloch wall in a continuous magnetic thin film). Conventional approaches to creating discrete magnetic and non-magnetic areas on a medium have focused on forming single bit magnetic domains that are completely separate from each other, either by depositing the magnetic domains as separate islands or by removing material from a continuous magnetic film to physically separate the magnetic domains. A substrate may be masked and patterned, and a magnetic material deposited over exposed portions, or the magnetic material may be deposited before masking and patterning, and then etched away in exposed portions. In either case, the topography of the substrate is altered by the residual pattern of the magnetic regions. Because the read-write head of a typical hard-disk drive may fly as close as 2 nm from the surface of the disk, these topographic alterations can become limiting. Thus, there is a need for a process or method of patterning magnetic media that has high resolution and does not alter the topography of the media, and an apparatus for performing the process or method efficiently for high volume manufacturing.

### SUMMARY

Embodiments described herein provide a chamber for processing a hard disk drive substrate, comprising a substrate support disposed in an internal volume of the chamber, a directional flow gas nozzle facing the substrate support, an inductive field source facing the substrate support, and a throttle valve having a gate member with a sealing surface for covering an outlet portal of the chamber.

Other embodiments provide an apparatus for processing hard disk drive substrates, comprising a processing chamber having an internal volume, an RF-biased substrate support, an inductive field source disposed near a wall of the chamber, and a gas nozzle disposed in a wall region of the chamber facing the substrate support, the gas nozzle having a diameter that increases smoothly in the direction that gas flows through the gas nozzle.

Other embodiments provide a method for processing a substrate, comprising disposing the substrate on a substrate support in a processing chamber, directing a process gas through a gas nozzle toward the substrate in a spreading pattern, ionizing a first portion of the process gas by coupling an inductive field into the process gas, ionizing a second portion of the process gas by coupling RF power to the substrate support, and selectively altering a magnetic property of a portion of the substrate by accelerating ions generated by the inductive field and the RF power toward the substrate.

Still other embodiments provide a cluster tool for processing a hard disk drive substrate, comprising a transfer chamber, and a patterning chamber coupled to the transfer chamber, wherein the patterning chamber comprises a chamber wall defining an internal volume of the patterning chamber, a substrate support disposed in the internal volume of the patterning chamber, a cone-shaped gas nozzle disposed in a wall region of the patterning chamber facing the substrate support, and an inductive field source disposed in a canister coupled to a wall of the patterning chamber facing the substrate support.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of an apparatus according to one embodiment.

FIG. 2A is a perspective view of a gas distributor according to another embodiment.

FIG. 2B is a cross-sectional view of an outlet end of a gas distributor according to another embodiment.

FIG. 2C is a bottom view of the outlet end of the gas distributor of FIG. 2B.

FIG. 3 is a schematic cross-sectional view of an energy source according to another embodiment.

FIGS. 4A-4D are schematic cross-sectional views of different examples of a chamber outlet valve according to another embodiment.

FIG. 5A is a schematic cross-sectional view of a chamber for processing hard disk drive substrates according to another embodiment.

FIG. 5B is a schematic cross-sectional view of the gas distributor from the chamber of FIG. 5A.

FIG. 5C is a schematic cross-sectional view of another gas distributor according to an embodiment.

FIG. 6 is a flow diagram summarizing a method according to another embodiment.

FIG. 7 is a plan view of a cluster tool for processing magnetically active substrates according to another embodiment.

FIG. 8A is a schematic cross-sectional view of a substrate support according to another embodiment.

FIG. 8B is an exploded perspective view of the substrate support of FIG. 8A.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments disclosed herein generally provide apparatus and methods for processing hard disk drive substrates. Hard disk drive substrates are generally formed by depositing layers on an aluminum or glass structural substrate. A magnetically active layer is formed on the substrate, and then subjected to a patterning process to produce a pattern of magnetic properties in the magnetically active layer. In one aspect, a resist is applied to the magnetically active layer, and physically patterned using a process such as nanoimprint lithography. The patterned resist coated substrate is subjected to ion bombardment to selectively alter one or more magnetic properties of the magnetically active layer in a pattern corresponding to the pattern formed in the resist material. The resist material is then removed, and the substrate finished by forming protective and lubricating layers over the patterned magnetically active layer.

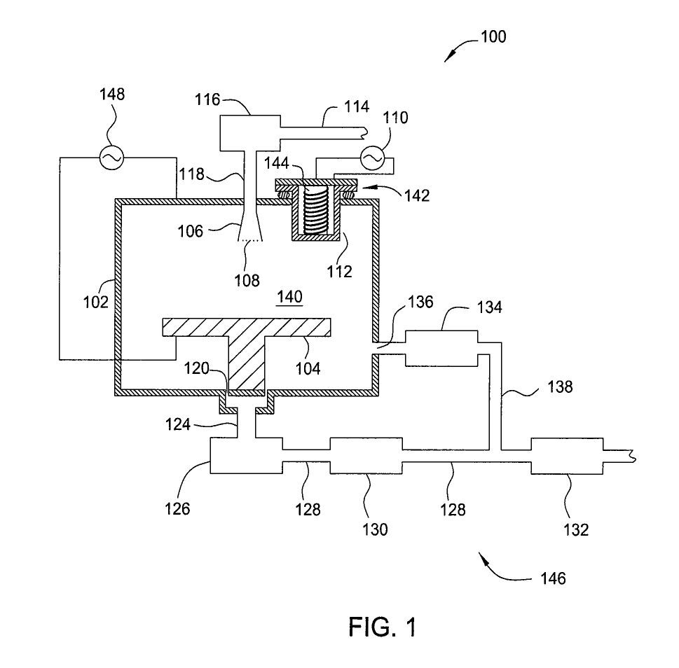

FIG. 1 is a schematic cross-sectional view of an apparatus 100 according to one embodiment. The apparatus 100 is generally useful for performing an ion bombardment process on a substrate. The apparatus 100 comprises a chamber wall 102 defining an internal volume 140 in which substrates will be processed. A substrate support 104 is disposed in the internal volume 140. In some embodiments, multiple substrates are processed simultaneously on a substrate holder having multiple substrate sites. The holder with the multiple substrates is disposed on the substrate support 104 to process the multiple substrates.

Facing the substrate support 104 is a gas distributor 106 disposed in a wall region of the apparatus 100. The gas distributor 106 may be a gas nozzle or other dispenser designed to provide gas in a pattern that substantially covers the substrate support. In one embodiment, the gas distributor 106 is a gas nozzle having a diameter that increases in the direction that gas flows through the gas nozzle. The gas nozzle may be cone-shaped, such as conical or frustroconical, and is generally positioned opposite a central portion of the substrate support 104. In one embodiment, the gas distributor 106 is configured to provide process gases in a spreading pattern.

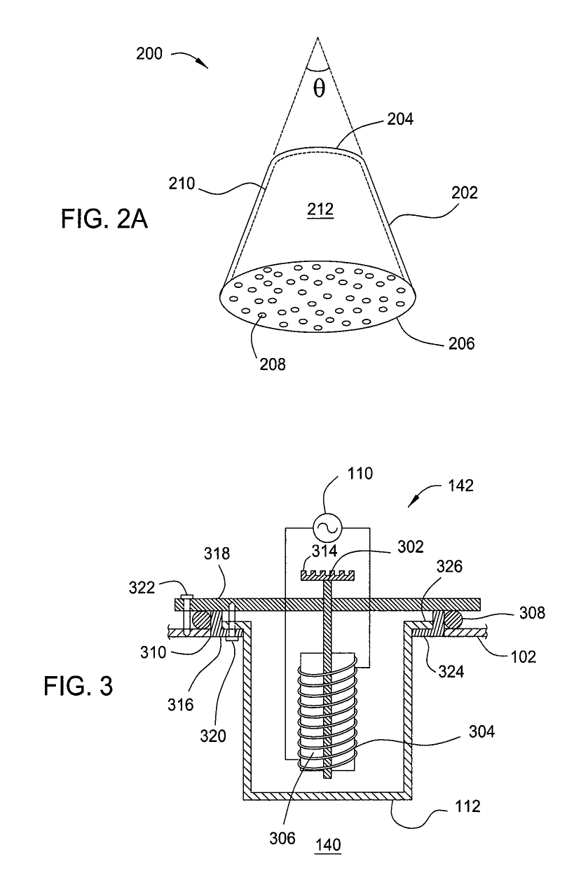

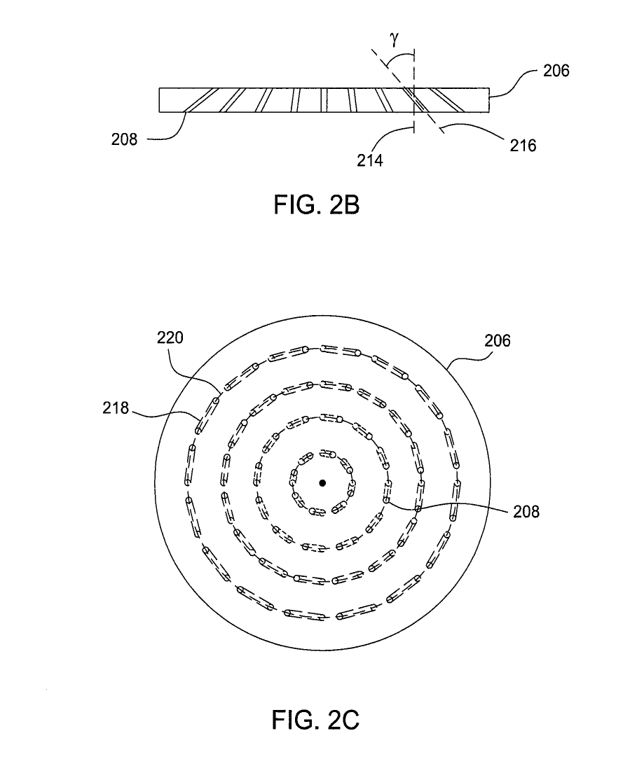

An example of a gas distributor that may be used in some embodiments is shown in FIG. 2A. The gas distributor 200 of FIG. 2A has a frustroconical shape, with a diameter that increases in the direction of flow. In the embodiment of FIG. 2A, the increase of diameter along the gas distributor is approximately linear, but other shapes may be used. In alternate embodiments, for example, the nozzle may have a flared shape according to any desired profile. The spreading pattern provided by the gas distributor 200 is influenced by the angle of divergence θ of the side wall 202. The gas distributor 200 has an internal surface 210 that defines an internal volume 212. In one embodiment, the internal volume 212 follows the shape of the side wall 202, providing the increasing diameter for gas to expand into as it flows through the gas distributor 200. A conduit (shown in FIG. 1) couples to the inlet 204 of the gas distributor 200, providing fluid communication with a gas source. The flow pattern of gas entering the inlet 204 of the gas distributor 200 spreads as the diameter of the gas distributor 200 increases. This spreading pattern continues as the gas exits the gas distributor 200 through an outlet end 206.

The outlet end 206 may be convex in some embodiments to promote the spreading pattern provided by the geometry of the gas distributor 200. The outlet end 206 comprises a plurality of outlet holes 208, which may be of any convenient size and distribution to provide desired flow and pressure drop characteristics. In one embodiment, the outlet holes 208 are between about 1/10″ and about ¼″ in diameter, such as about ⅛″ in diameter, to provide capability to surge gas flow at a high rate, if needed, while preventing back-flow of plasma from the processing chamber to the gas distributor 200 and feed system. In most embodiments, the outlet end 206 will have between about 10 and about 200 outlet holes 208, for example between about 50 and about 100 holes, such as about 60 holes. In one embodiment, the outlet end 206 has a substantially spherical convex shape with a radius of curvature at least five times its diameter. Curvature of the outlet end 206 provides some outlet holes directly facing the central portion of the substrate support (shown in FIG. 1) while other outlet holes point toward more peripheral portions of the substrate support. Gas exiting such an outlet plate is thus encouraged to spread, substantially covering substrates disposed on the substrate support.

In an alternate embodiment, the outlet end 206 may be flat or concave to produce different flow patterns of the gas as it leaves the gas distributor 200. A flat outlet plate will diminish or eliminate the spreading pattern, depending on the geometry of the gas distributor 200. A gas distributor with a side wall having angle of divergence a that is large, such as greater than about 120°, may use a flat outlet plate to reduce the spread of gases as they exit the outlet plate. A gas distributor with a side wall having small angle of divergence, such as less than about 30°, with a flat outlet plate may produce a gas stream with very little spreading pattern. A concave outlet plate may be used to reduce, eliminate, or reverse a spreading pattern in some embodiments. The different side wall and outlet plate geometries may be used in embodiments requiring control of the gas density profile across the substrate support. Likewise, distribution and sizing of the outlet holes 208 may be adjusted to control density profile. For example, if desired, the outlet holes 208 may have multiple sizes, and larger holes may be located toward the periphery of the outlet end 206, while smaller holes are located toward the center, to spread more gas to peripheral portions of the substrate support.

In some embodiments, the outlet holes 208 may be bored through the outlet end 206 at one or more angles to provide directional flow through the outlet holes 208. In one embodiment, outlet holes 208 located near the central region of the outlet end 206 may be bored substantially perpendicular to a plane tangent to the outlet end 206 (ie “straight through”), and outlet holes 208 located near the peripheral region of the outlet end 206 may be bored at an angle pointing away from the central region of the outlet end 206 to foster divergent gas flow.

FIG. 2B is a cross-sectional view of an outlet end 206 according to another embodiment. The outlet end 206 of FIG. 2B is an outlet plate. The outlet holes 208 of the outlet end 206 of FIG. 2B are generally angled with respect to a line 214 perpendicular to a surface of the outlet end 206. The outlet holes 208 are bored along a line 216 that forms an angle γ with respect to the perpendicular line 214. In the embodiment of FIG. 2B the angle γ increases with distance from the center of the outlet end 206 to provide a divergent flow pattern for gas flowing through the outlet end 206.

In another embodiment, the outlet holes 208 may be bored at an angle that facilitates a rotating flow of gas emerging from the gas distributor 200. FIG. 2C is a top view of an outlet end 206 according to another embodiment. Although the embodiment illustrated in FIG. 2C shows only a few outlet holes 208 for clarity, the outlet end 206 of FIG. 2C will also generally have outlet holes 208 distributed across the outlet plate as illustrated in FIG. 2A. Similar to the embodiment shown in FIG. 2B, the outlet holes 208 of FIG. 2C are bored at an angle through the outlet end 206 as illustrated by phantom bores 218. The bores 218 are oriented along concentric circles 220, however, in the embodiment of FIG. 2C, to provide a circular flow pattern for gas flowing through the outlet end 206. The bores 218 may increase in length with distance from the center of the outlet end 206, if desired, to reduce turbulence in the circular flow pattern. Additionally, the bores 218 may be angled according to the embodiment of FIG. 2B to provide a divergent circular flow pattern, if desired.

In another alternate embodiment, the gas distributor 200 may feature outlet holes 208 on a side wall portion of the gas distributor 200, such as on the side wall 202. As described above in connection with outlet holes 208 formed in the outlet end 206, outlet holes 208 formed in the side wall 202 may each comprise an angled bore to provide directional flow, such as divergent flow, circular flow, or both.

Referring again to FIG. 1, the gas distributor 106 has an outlet plate 108 that may be any of the types described above. The gas distributor 106 extends through the chamber wall 102 and is coupled to a high-flow mass flow controller 116 by a first conduit 118, which is coupled to a gas source (not shown) by a second conduit 114. The high-flow mass flow controller 116 is used to control gas flows at a wide variety of flow rates to accommodate various process regimes used for ion bombardment and thermal management. In some embodiments, the gas flow rate during a cooling process may be more than 100 times the gas flow rate during ion bombardment.

The capability to ionize a portion of the process gas is provided by an ion source 142, which may be an inductive field source, disposed in a wall region of the apparatus 100. The ion source 142 projects energy into the process gas in the internal volume 140 of the apparatus 100. In one embodiment, the ion source 142 comprises an inductive core 144 disposed in a receptacle 112, which couples the ion source 142 to the chamber wall 102, allowing the inductive core 144 to penetrate the chamber wall 102 while isolating the inductive core 144 from the processing environment of the internal volume. A power source 110, which may comprise RF, DC, or pulsed DC power, is coupled to the inductive core 144 to produce the inductive field.

An example of an ion source that may be used for some embodiments is shown in FIG. 3. The ion source 142 shown in FIG. 3 is an inductive field source, which comprises an inductive core 144 disposed in a receptacle 112, which may be a canister. The receptacle 112 is generally formed from a dielectric material, such as glass, ceramic, or plastic, resistant to the processing environment of the internal volume 140. The receptacle 112 is disposed in an opening 310 of the chamber wall 102, allowing the ion source 142 to penetrate the chamber wall 102 to the internal volume 140 of the chamber. The receptacle 112 protects the inductive core 144 from the reactive conditions experienced in the chamber internal volume 140 during processing. The receptacle 112 is coupled to a lid 318 by a ring 316, and by one or more first fasteners 320. The ring 316 has an inwardly extending lip 324 that mates with an outwardly extending ledge 326 of the receptacle 112. The one or more first fasteners 320 secure the lip 324 against the ledge 326, anchoring both to the lid 318, which may be a plate. The lid 318 is attached to the chamber wall 102 by a second fastener 322, which may be formed as an integral part of the lid 318 in some embodiments. The opening 310 is sealed by a sealing member 308, which is generally formed from a compliant material that deforms under pressure to seal the space between the lid 318 and the chamber wall 102.

The inductive core 144 comprises a ferritic part 304 and a conductive part 302 that protrudes from the receptacle 112. The ferritic part 304 provides the electromagnetic activity required to produce the inductive field, while the conductive part 302 provides thermal management for the inductive core 144. The protruding portion of the conductive part 302 is thermally coupled to a thermal member 314 that supplies or removes heat to control the temperature of the inductive core. In an alternate embodiment, thermal management may be accomplished by providing one or more conduits through the ferritic part 304 for flowing a thermal medium through the ferritic part 304.

The core is encompassed by a coil 306, which is coupled to the power source 110. As power is provided to the coil 306, an inductive field emanates from the ferritic part 304, which may rise in temperature due to the energy flux therethrough. Any heat generated is conducted to the conductive part 302, and out to the thermal member 314. The ferritic part 304 is generally made of a paramagnetic or ferromagnetic material, such as a metal or alloy, sometimes comprising iron. The conductive part 302 generally comprises a material that exhibits at most weak paramagnetism or ferromagnetism but has good thermal conductivity. The conductive part 302 may thus comprise a metal or metal alloy such as copper, or copper mixed with another metal such as aluminum. In an alternate embodiment, a gas or liquid, such as water, may be provided through conduits formed in the ferritic part 304.

In alternate embodiments, any plasma ignition source may be used to create a plasma in the processing chamber. Such plasma ignition sources include, but are not limited to, radiant energy sources, inductive sources, and capacitive sources, which may be located inside the processing chamber or outside the processing chamber. In one embodiment, a UV source may be located outside the processing chamber, but disposed to emit radiant energy through a window into the processing chamber. In another embodiment, a pair of re-entrant tubes may be disposed along one or more walls of the processing chamber and coupled to powered inductive coils to admit process gases from the chamber and excite the process gases into a plasma. In another embodiment, a capacitive plasma source may be disposed inside the processing chamber. The capacitive plasma source may also be a bias source, or may be additional to the bias source.

Referring again to FIG. 1, gases exit the apparatus 100 through an exhaust system 146. The exhaust system 146 generally comprises at least one vacuum pump with piping and valves to expose the chamber internal volume 140 to the pump suction. The exhaust system 146 of FIG. 1 comprises a low vacuum pump 132, which may be a roughing pump in some embodiments, and a high vacuum pump 126, which may be a turbo pump in some embodiments. The low vacuum pump 132 is coupled to a first outlet portal 136 of the apparatus 100 by a first exhaust conduit 138, mediated by a first valve 134. The low vacuum pump 132 is also coupled to the high vacuum pump 126 by a second conduit 128, mediated by a second valve 130. The high vacuum pump 126 is coupled to a second outlet portal 120 of the apparatus 100 by a throttle valve 124. The throttle valve 124 may be a low conductance throttle valve in some embodiments, and enables a wide range of flow rates through the high vacuum pump 126, allowing fast pump-down of the chamber. In operation, the low vacuum pump is used to reduce the pressure of the internal volume 140 from atmospheric pressure to about 1 Torr with the first valve 134 open and the second valve 130 closed. The first valve 134 is then closed and the second valve 130 and the throttle valve 124 opened, and the combined suction of the low vacuum pump 132 and the high vacuum pump 126 reduces the pressure of the internal volume 140 to 1 milliTorr or less. The pressure of the internal volume 140 may be raised to 10 Torr or more rapidly by substantially closing the throttle valve 124 while maintaining gas flow into the internal volume 140 through the gas distributor 106. The apparatus 100 may be pumped down by opening the throttle valve 124.

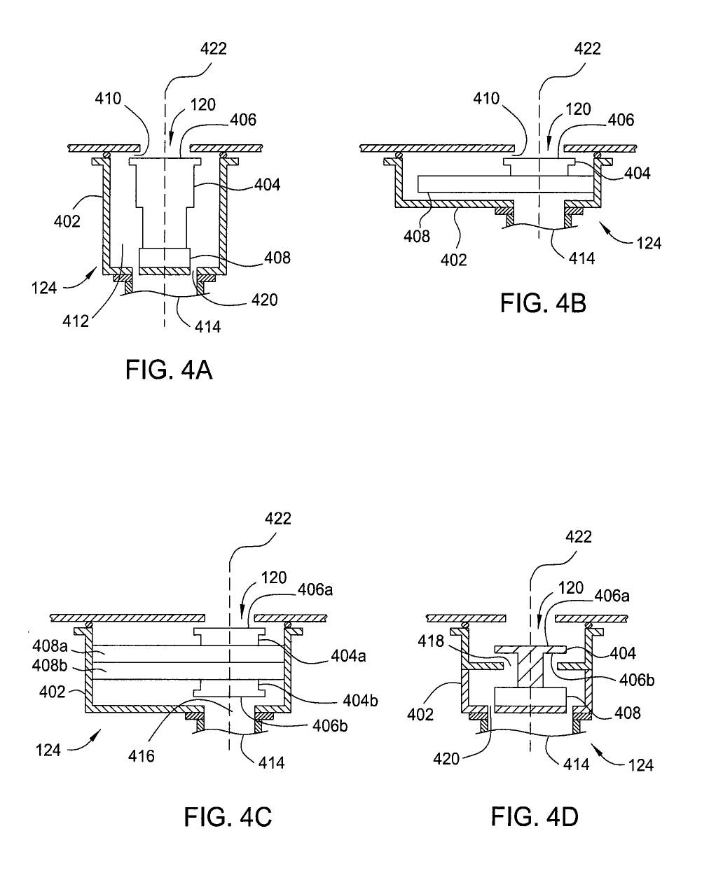

Examples of throttle valves that may be used in embodiments described herein are shown in schematic cross-sectional FIGS. 4A-4D. Each of the embodiments in FIGS. 4A-4D has a valve body 402 and a gate member 404 positioned to block the outlet portal 120 of the chamber. Each of the gate members 404 has a sealing surface 406 facing the outlet portal 120 and the chamber wall 102. An actuator 408 is coupled to each gate member 404, and contained within the valve body 402.

In the embodiment of FIG. 4A, the actuator 408 is configured to actuate the gate member 404 along an axis 422 of the valve body 402 substantially perpendicular to a plane defined by the chamber wall 102 surrounding the outlet portal 120. In one example, the actuator 408 may actuate the gate member 404 using pneumatic means by applying pressure to the gate member 404 to urge the gate member 404 toward the outlet portal 120. In another example, the actuator 408 may actuate the gate member 404 using magnetic means by opposing two magnets, at least one of which is an electromagnet, inside the valve body 402.

When the gate member 404 is advanced toward the outlet portal 120, it approaches the chamber wall 102 surrounding the outlet portal 120, and the sealing surface 406 restricts gas flow through the outlet portal 120 by closing a gap 410 between the sealing surface 406 and the chamber wall 102. As the sealing surface 406 of the gate member 404 contacts the chamber wall 102, gas flow stops. The actuator 408 maintains positive pressure on the gate member 404, urging the sealing surface 406 against the chamber wall 102 to maintain a seal as pressure increases in the chamber. When the valve 124 is open, gas flowing through the outlet portal 120 flows through the space 412 between the gate member 404 and the valve body 402, and out through one or more openings 420 in the valve body 402 that communicate with an outlet conduit 414. The outlet conduit 414 couples the throttle valve 124 to the high vacuum pump 126 (FIG. 1). Any number of such openings may be provided in the valve body 402 surrounding the actuator 408 of FIG. 4A. The single axis movement of the gate member 404 provides large turndown of gas flow through the valve body 402, enabling rapid pressuring and depressuring of the chamber, if desired, as well as flow control at the relatively low flow rates required during processing.

In the embodiment of FIG. 4B, the actuator 408 provides movement of the gate member 404 in two dimensions. The actuator 408 advances and retracts the gate member 404 along the axis 422 of the valve body 402, and moves the gate member 404 in a direction perpendicular to the valve body axis 422. The axial motion of the gate member 404 provides sealing of the outlet portal 120, as described above. The lateral motion provides additional throughput by removing the gate member 404 from the path of gas exiting the chamber through the outlet portal 120. The actuator 408 may be positioned in a location convenient for moving the gate member 404 without unduly obstructing gas flow through the throttle valve 124 when the throttle valve 124 is open. In one embodiment, the actuator 408 may move the gate member 404 laterally in a swinging motion. In another embodiment, the actuator 408 may comprise a rail and lateral motion impeller to move the gate member 404 along the rail.

In the embodiment of FIG. 4C, a dual valve independently controls gas flow through two portals of the valve body 402. The dual valve comprises two gate members 404a and 404b, wherein each gate member is coupled to an actuator 408a and 408b. The actuators 408a/b move the gate members 404a/b independently to provide more degrees of freedom in controlling gas flow through the valve. The dual valve may also provide tighter shutoff by positively sealing the outlet portal 120 of the chamber and an outlet portal 416 of the valve body 402 simultaneously, if desired. Any potential leakage past the sealing surface 406a that seals the outlet portal 120 is compensated by the sealing surface 406b that seals the outlet portal 416 of the valve body 402.

In the embodiment of FIG. 4D, the actuator 408 moves the gate member 404 in a manner similar to the embodiment of FIG. 4A, but the valve body 402 additionally comprises an intermediate opening 418 between the sealing surface 406a of the gate member 404 and the outlet portion of the valve body 402 comprising openings 420 leading into the outlet conduit 414. The gate member 404 thus has two sealing surfaces 406a and 406b facing the chamber outlet portal 120 and the intermediate opening 418, respectively, to provide a seal against the outlet portal 120 of the chamber wall 102 or against the intermediate opening 418 in the valve body 402, for additional degrees of freedom in controlling gas flow.

In some embodiments, the gate member 404 has a flat sealing surface 406 that contacts the outer surface or the inner surface of the chamber wall 102 to seal the outlet portal 120. In other embodiments, the sealing surface 406 of the gate member 404 may have a raised portion or a protrusion, which may be a plug in some embodiments, that extends into the outlet portal 120, optionally contacting an edge of the outlet portal 120 to enhance the seal.

Referring again to FIG. 1, the substrate may be biased by coupling an RF source 148 to the substrate support 104 and the chamber wall 102. Alternately, the RF source 148 may be coupled to the gas distributor 106. Coupling the RF source to the chamber wall 102, as shown in FIG. 1, requires appropriate electrical isolation members, which are not shown, to isolate the substrate support 104 from the chamber wall 102. The RF source 148 is normally coupled through an impedance matching network (not shown), as is known to the art.

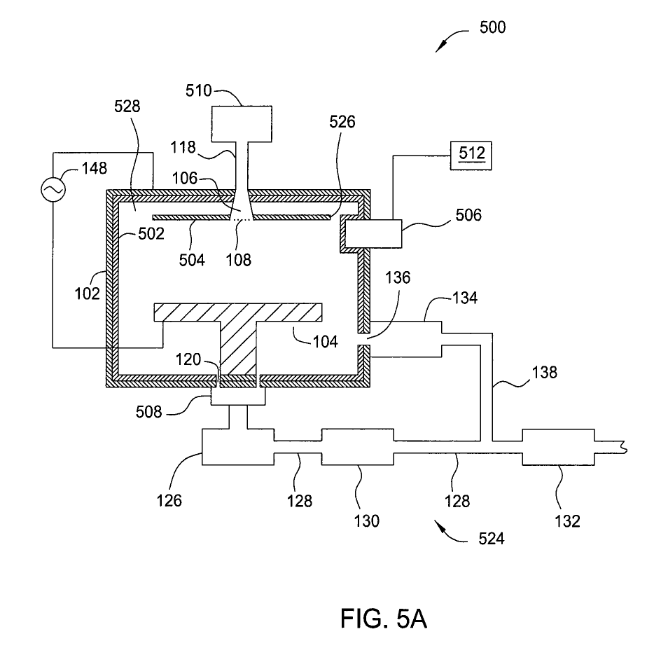

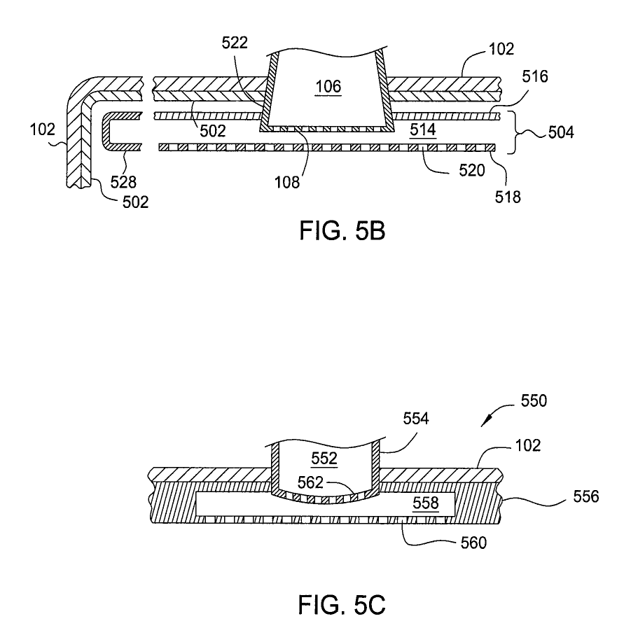

FIG. 5A is a schematic cross-sectional view of a processing chamber 500 according to another embodiment. The processing chamber 500 of FIG. 5A comprises a chamber wall 102 that defines an internal volume 140, similar to the embodiment of FIG. 1. A substrate support 104 is disposed in the internal volume 140 of the chamber 500. A process gas source 510 provides process gases through a conduit 118, dispensing the process gases into the chamber 500 through a gas distributor 106 having an outlet plate 108. Gases exit the chamber through an outlet portal 120. The process gas source 510 may comprise a high-flowrate mass flow controller, as described above in connection with FIG. 1, in some embodiments.

The chamber 500 further comprises a liner 502 disposed on the internal surfaces of the chamber wall 102 to reduce or eliminate exposure of chamber internal surfaces to process conditions. The chamber liner is generally made of a conductive, non-oxidizing material, such as silicon, graphite or graphitic carbon, or anodized aluminum, and covers surfaces that would otherwise be exposed to reactive conditions present during processing. In some embodiments, the chamber liner 502 covers all internal surfaces from the gas distributor 106 to the outlet portal 120. In other embodiments, the chamber liner 502 covers internal surfaces above the substrate support 104.

The chamber 500 further comprises a shield 504 coupled to the gas distributor 106 and spaced apart from the chamber liner 502. The shield 504 provides further protection from processing conditions for portions of the chamber wall 102 and chamber internal components, such as the gas distributor 106. In one embodiment, the gas distributor 106 extends through the shield 504, exposing the outlet plate 108 of the gas distributor 106 to the chamber internal environment. In another embodiment, the shield 504 is a gas distribution plate that covers the outlet plate 108 of the gas distributor 106 to protect both the gas distributor 106 and the outlet plate 108 from the process environment. The shield 504 has an edge 526 that forms a gap 528 between the edge 526 of the shield 504 and the chamber liner 502. The gap 528 is sized to prevent intrusion of ions above the shield 504 while minimizing disruption to the chamber electromagnetic characteristics. In one embodiment, the gap 528 has a width between about 1 mm and about 50 mm.

In embodiments wherein the shield 504 is a gas distribution plate, the shield has openings to allow process gas to exit into the chamber. FIG. 5B is a detailed cross-sectional view of an embodiment of the shield 504 of FIG. 5A. The shield 504 of FIG. 5B is a gas distribution plate, and covers the outlet plate 108 of the gas distributor 106. The shield 504 of FIG. 5B has an internal volume 514 defined by an upper wall 516 and a lower wall 518 spaced apart from the upper wall 516. The upper wall 516 and lower wall 518 are connected at an edge portion 528 of the shield 504 to define the internal volume 514 of the shield 504. The upper wall 516 of the shield 504 is disposed about the gas distributor 106 such that the gas distributor 106 penetrates the upper wall 516 of the shield. Gas exits the outlet plate 108 of the shield 106 into the internal volume 514 of the shield, spreading through the internal volume 514 before exiting the shield 504 through openings 520 formed in the lower wall 518 of the shield 504. The shield generally prevents reactive species in the processing chamber from contacting the side wall 522 of the gas distributor 106. The openings 520 in the lower wall 518 of the shield 504 of FIG. 5B may be sized and arranged to influence gas distribution within the chamber internal volume, if desired. For example, to force gas from the gas distributor 106 to spread to the outer extremities of the shield 504, the openings 520 in a central region of the shield 504 may be made smaller, less dense, or both, relative to the openings 520 in a peripheral region of the shield 504.

In an alternate embodiment, the shield 504 may be eliminated by extending the chamber liner 502 to cover the side wall and outlet plate 108 of the gas distributor 106. Openings, such as the openings 520 of the shield 504 of FIG. 5B may be provided in the chamber liner 502 to facilitate distribution of gas from the gas distributor 106.

In one embodiment, the chamber liner may have an internal volume, and the gas distributor may be positioned such that the outlet plate releases process gases into the internal volume of the chamber liner. FIG. 5C is a schematic cross-sectional view of a gas distribution assembly 550 of a chamber, such as the chamber 500, for processing hard disk drive substrates. The gas distribution assembly 550 comprises a gas distributor 552, which may be similar to the gas distributor 106 of FIGS. 1, 2A, 5A, and 5B. The gas distributor 552 of FIG. 5C is shown with parallel side walls 554, rather than side walls that converge at an angle. As described above, the gas distributor 552 may use a convex outlet plate 562 to create a spreading flow pattern of gas as it leaves the gas distributor 552.

The gas distribution assembly 550 further comprises a chamber liner 556 with an internal volume 558 formed therein for receiving the outlet plate 562 of the gas distributor 552. The chamber liner 556 also has outlet portals 560 formed therein for gases to exit the internal volume 558 of the chamber liner 556. The outlet portals 560 may be arranged by size and density to control uniformity of gas flow leaving the internal volume 558 of the chamber liner 556, if desired. Use of a chamber liner such as that described in connection with FIG. 5C reduces the need for a separate shield such as the shield 504 of FIGS. 5A and 5B.

It should be noted that the gas distribution portions of the shield 504 of FIG. 5B and the chamber liner 556 of FIG. 5C may be shaped to encourage gas flow according to a desired pattern, and may include any of the features described in connection with the embodiments of FIGS. 2A-2C. For example, the region of the shield 504 and the chamber liner 556 having openings 520 and 560, respectively, may be convex or concave, if desired, to further direct gas flow in a desired pattern.

In another embodiment, the gas distributor 106 and outlet plate 108 may be made of the same, or similar, material as the chamber liner 502.

Referring again to FIG. 5A, the processing chamber 500 further comprises an exhaust system 524 coupled to one or more outlet portals. The exhaust system comprises a low vacuum pump 132 and a high vacuum pump 126. The low vacuum pump is coupled to the chamber 500 by a conduit 138 and a first valve 134. The first valve 134 is coupled to a first outlet portal 136 in the chamber wall 102, exposing the outlet portal 136 to the suction of the low vacuum pump 132, substantially as in the embodiment of FIG. 1. A second valve 130 couples the low vacuum pump 132 to the high vacuum pump 126 through the conduit 128. The high vacuum pump 126 is coupled to the outlet portal 120 by a throttle valve 508 configured to control gas flow at very low flowrates while providing capability to pressure and depressure the chamber 500 rapidly. In some embodiments, the throttle valve 508 comprises a z-motion activator coupled to a gate member (not shown) that seats against the chamber wall 102 and closes off the outlet portal 120. Embodiments of throttle valves discussed above in connection with FIGS. 4A-4D may be used in some embodiments.

The chamber 500 further comprises an energy source 506 disposed in an opening of the chamber wall 102. Coupled to a power source 512, the energy source 506 provides electromagnetic energy to the process gases in the internal volume 140 of the chamber 500. The electromagnetic energy may be an electric field, a magnetic field, an electromagnetic field, or a varying electromagnetic field, such as electromagnetic radiation. In embodiments wherein the energy source 506 forms an electric field or magnetic field in the chamber internal volume 140, the electric or magnetic field may be a varying electric or magnetic field. In some embodiments, the energy source 506 may be a DC, pulsed DC, or RF electric field source. In other embodiments, the energy source 506 may be a DC, pulsed DC, or RF inductive field source. In other embodiments, the energy source 506 may be a source of electromagnetic radiation, such as UV, microwave, thermal, or deep-UV radiation. The energy source 506 may be disposed in a top wall, side wall, or bottom wall of the chamber 500, so long as the energy source 506 can couple energy into the internal volume 140 between the substrate support and the shield 504. In some embodiments, two or more such energy sources may be positioned at different locations around the chamber wall 102.

The chamber liner 502 may be configured to cover the energy source 506, as shown in FIG. 5A. Alternately, the energy source may be contained in a receptacle (not shown in FIG. 5A) disposed in a opening formed through the chamber wall 102 and the chamber liner 502, the receptacle being made of a resistant material similar to the material of the chamber liner 502.

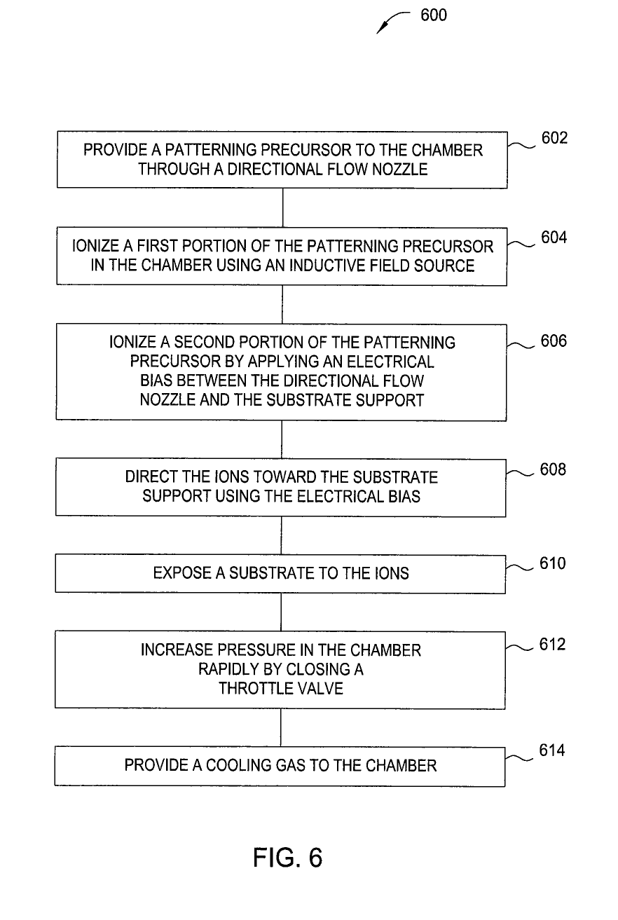

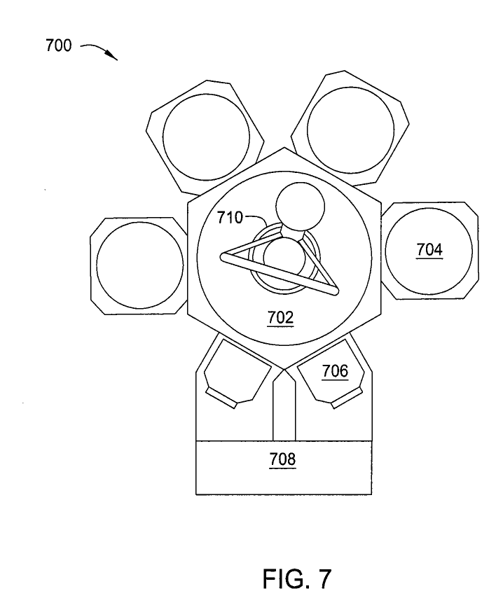

FIG. 6 is a flow diagram summarizing a method 600 according to another embodiment. The method 600 is useful for processing hard disk drive substrates or other magnetic media. A substrate to be processed is disposed in a processing chamber. At 602, a patterning precursor is provided to the processing chamber through a directional flow nozzle. The patterning precursor is selected to modify a magnetic property of the substrate by implanting into selected regions of the substrate surface. Patterning precursors generally useful for embodiments described herein include compounds having elements selected from the group of helium, hydrogen, oxygen, nitrogen, boron, phosphorus, arsenic, fluorine, silicon, platinum, aluminum, and argon. Substances useful as patterning precursors include elemental hydrogen (H₂), helium (He), oxygen (O₂), nitrogen (N₂), fluorine (Fl₂), and argon (Ar), as well as lower hydrides and fluorides of boron, silicon, and carbon, such as borane (BH₃) , diborane (B₂H₆), silane (SiH₄), disilane (Si₂H₆), methane (CH₄), ethane (C₂H₆), boron trifluoride (BF₃), and diboron tetrafluoride (B₂F₄).

At 604, a first portion of the patterning precursor is ionized in the chamber using an energy source, which may be an inductive field source. An inductive field source may be powered by RF, DC, or pulsed DC power to produce a static or varying magnetic or electromagnetic field inside the chamber. In some embodiments, other energy sources, such as electromagnetic radiation, may be used. For example, thermal, UV, deep-UV, or microwave radiation may be projected into the chamber to ionize the first portion of the patterning precursor. In one embodiment, an inductive magnetic field is generated by an inductive source powered by RF at a power level between about 50 W and about 5,000 W and a frequency between about 300 kHz and about 20 MHz.

At 606, a second portion of the patterning precursor is ionized by applying an electrical bias between the directional flow nozzle and the substrate support. The electrical bias may be applied using RF, DC, or pulsed DC power coupled to the directional flow nozzle, the substrate support, or both. The electrical bias accelerates ions generated by the energy source utilized at 604. The accelerated ions collide with other neutrals, creating more ions throughout the chamber.

At 608, the ions are directed toward the substrate support by action of the electrical bias. In one embodiment, RF power is coupled to the substrate support to generate an electrical bias having RMS voltage between about 500 V and about 5,000 V at a power level between about 50 W and about 5,000 W and a frequency between about 300 kHz and about 20 MHz to impart energy between about 0.2 keV and about 5.0 keV to each ion.

substrate is exposed to the ions at 610. The ions impact the substrate surrace, changing a magnetic property of the substrate surface by imparting energy to magnetic domains in the substrate surface through collision or implantation. In some embodiments, portions of the substrate surface may be masked to prevent ions reaching those portions. In such embodiments, a pattern of magnetic properties is created in the substrate surface according to the pattern of the mask.

As the substrate is exposed to the ions, heat energy generated by the impacting ions builds up in the substrate, causing the temperature of the substrate to rise. In order to manage this temperature rise, the electrical bias is discontinued, and pressure is rapidly increased in the chamber at 612 by closing a throttle valve disposed on an outlet portal of the chamber. The higher pressure provides more mass in the chamber to provide heat conductance out of the substrate. A cooling gas is provided to the chamber at 614 to facilitate temperature control of the substrate. Flow of the cooling gas may be provided at a rate between about 0 slm and about 5 slm. Magnetic properties of substrates may be undesireably altered by elevated temperatures, so thermal management allows desired magnetic properties to be preserved.

FIG. 7 is a plan view of a cluster tool 700 for processing magnetically active substrates according to another embodiment. The cluster tool 700 comprises a transfer chamber 702 with at least one substrate handler 710 disposed therein. A plurality of process chambers such as process chamber 704 are coupled to the transfer chamber 702. One or more load lock chambers 706 are coupled to the transfer chamber 702 and to a factory interface 708. The plurality of process chambers may comprise an ion exposure chamber such as the chambers 100 and 500 of FIGS. 1 and 5A, respectively. The plurality of process chambers may also comprise a resist stripping chamber, a plasma cleaning chamber, and one or more deposition chambers. In operation, a substrate, or a substrate holder carrying a plurality of substrates, is positioned in one of the load lock chambers 706 by a substrate handler (not shown) disposed within the factory interface 708. The substrate handler 710 retrieves the substrate from the load lock chamber 706 and deposits it in a process chamber 704 for processing. The substrate handler may transfer the substrate between various of the process chambers 704 to perform a programmed sequence of operations before returning the substrate to one of the load lock chambers 706. In one embodiment, the plurality of process chambers 704 may comprise a plurality of ion exposure chambers, for example two or three ion exposure chambers, such as the chambers 100 and 500 of FIGS. 1 and 5A, respectively.

In one embodiment, a substrate having a magnetically active surface and a patterned resist layer formed thereon is positioned in a load lock chamber 706. The substrate handler 710 disposes the substrate in a process chamber 704 similar to the chamber 100 of FIG. 1 for ion exposure. The ion exposure chamber modifies a magnetic property of the substrate according to the pattern of the patterned resist. The substrate may undergo multiple phases of ion exposure in different chambers of the cluster tool, followed by resist stripping in a stripping chamber. The substrate may also undergo multiple cycles of ion exposure in a single chamber. The resist stripping may be performed in the same chamber as the ion exposure, or in a different chamber.

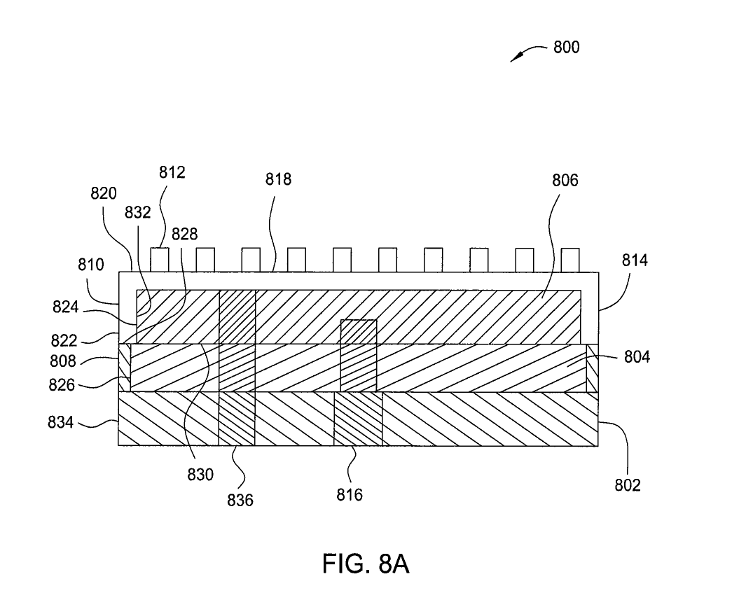

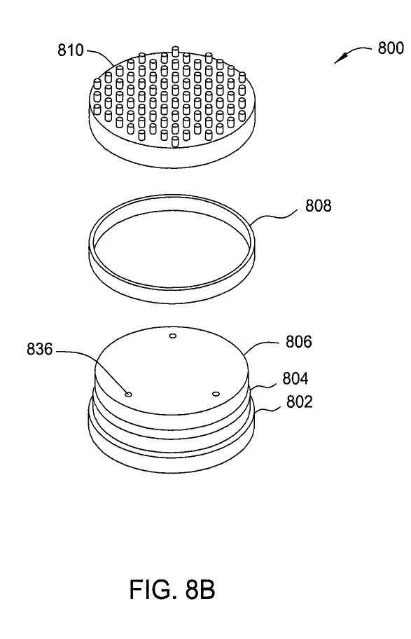

FIG. 8A is a cross-sectional view of a substrate support 800 according to another embodiment, which may be used in conjunction with the various embodiments of processing chambers, gas distributors, and energy sources described herein. The substrate support 800 generally comprises a base member 802, an insulating member 804, and a conductive member 806 that may be used to apply energy to a substrate disposed on the substrate support for any desired reason. The base member 802, insulating member 804, and conductive member 806 each comprises a conduit 816, all of which align to provide access to an interior portion of the conductive member 806 for coupling energy into the conductive member 806. In one embodiment, an RF source may be electrically coupled to the substrate support 800 by inserting a wire or conductive plug into the conduit 816. The insulating member 804 generally comprises a dielectric material, such as ceramic, plastic, or glass. In one embodiment, a polymer material, such as polycarbonate, is used for the insulating member 804. The base member 802 generally provides structural support, and may comprise any material adapted for that purpose.

The substrate support 800 comprises a supporting member 810 with a plurality of extensions 812 for engaging substrates above a surface 818 of the supporting member 810. In one embodiment, substrates may rest on the extensions 812, and may be held in place by gravity or by a grasping mechanism (not shown) coupled to each extension. In one embodiment, the extensions 812 may be shaped to engage an opening in the center of each substrate. The supporting member 810 generally comprises a dielectric material, such as glass, ceramic, or polymer. In one example, a supporting member comprises between about 10 and about 16 extensions, such as about 14 extensions, for engaging substrates.

The supporting member 810 also comprises a shoulder portion 814 that extends from an edge portion 820 of the supporting member 810, allowing the supporting member 810 to engage with the conductive member 806. The shoulder portion will generally form an angle with the edge portion 820 of the supporting member 810, as shown in the cross-sectional view of FIG. 8, and in some embodiments may be substantially perpendicular to the edge portion 820. In another embodiment, the supporting member 810 may be a substantially flat palette, with a separate ring member replacing the shoulder portion 814.

In one embodiment, the supporting member 810 has a circular shape with an outer diameter 822 that exceeds an outer diameter 832 of the insulating member 804, but is substantially the same as, or less than, an outer diameter 834 of the base member 802, and an inner diameter 824 that is less than an outer diameter of the insulating member 804. In one embodiment, the inner diameter 824 of the supporting member 810 is substantially the same as an outer diameter 832 of the conductive member 806 to facilitate contact, physical and electrical, between the supporting member 810 and the conductive member 806.

A process kit 808 may be disposed between the base member 802 and the supporting member 810, surrounding and contacting the insulating member 804 at an inner surface 826 thereof. In one embodiment, the process kit has a thickness that is substantially equal to the thickness of the insulating member 804, such that a lower surface 828 of the shoulder portion 814 of the supporting member 810 contacts an upper surface 830 of the insulating member 804. In another embodiment, the process kit may have a thickness greater than that of the insulating member 804, such that the process kit extends above the upper surface 830 of the insulating member 804. In such an embodiment, the lower surface 828 of the supporting member 810 is spaced apart from the upper surface 830 of the insulating member 804, and the process kit 808 has a shoulder that contacts the upper surface 830 of the insulating member 804 and extends partway up the conductive member 806 to meet the supporting member 810.

The supporting member 810 is separable from the substrate support 800 for transporting substrates into and out of processing equipment described herein. Each of the base member 802, the insulating member 804 and the conductive member 806 has an opening 836 for operation of a lift mechanism (not shown) for raising the supporting member 810 above the conductive member 806 for access by a handling mechanism (not shown). One opening is shown in the cross-sectional view of FIG. 8A, but multiple openings are generally provided.

The substrate support 800 may be thermally controlled by including conduits through one or more members of the substrate support 800 for flowing thermal control fluids therethrough. In one embodiment, the conductive member 806 has conduits (not shown) for flowing a thermal medium, such as a cooling gas or liquid, through the conductive member 806 to moderate heating from electrical energy input.

FIG. 8B is an exploded perspective view of the substrate support 800 of FIG. 8A. In the embodiment of FIG. 8B, three openings 836 are shown for the lift mechanism to access the supporting member 810.

While the foregoing describes some embodiments, other and further embodiments may be devised without departing from the basic scope of the invention.

What is claimed is:

1. A chamber for processing a hard disk drive substrate, comprising:
an enclosure defining an internal volume of the chamber;
a substrate support disposed in the internal volume;
a directional flow gas nozzle facing the substrate support;
an inductive field source facing the substrate support; and
a throttle valve having a gate member with a sealing surface for covering an outlet portal of the chamber.

2. The chamber of claim 1, wherein the directional flow gas nozzle has a diameter that increases in the direction that gas flows through the nozzle.

3. The chamber of claim 1, wherein the directional flow gas nozzle has a convex outlet plate comprising a plurality of outlet holes.

4. The chamber of claim 1, wherein a portion of the inductive field source protrudes into the interior volume, and the inductive field source is isolated from the interior volume.

5. The chamber of claim 1, wherein the directional gas flow nozzle and the inductive field source are disposed in a wall region of the chamber facing the substrate support.

6. The chamber of claim 1, wherein the gate member of the throttle valve is actuated along an axis of the throttle valve.

7. The chamber of claim 1, wherein the directional flow gas nozzle and the inductive field source are disposed in a wall region of the chamber facing the substrate support, the directional flow gas nozzle has a frustroconical shape, the inductive field source comprises an inductive core disposed in a receptacle that extends into an interior portion of the chamber and isolates the inductive core from the interior portion of the chamber, and the throttle valve comprises an opening and a gate member for mating with the opening, the gate member being actuated along an axis of the low conductance throttle valve.

8. The chamber of claim 1, wherein the directional flow gas nozzle comprises a plurality of outlet holes bored at an angle through an outlet end of the directional flow gas nozzle, wherein the bore angle of the outlet holes varies from a central region of the outlet end to a peripheral region of the outlet end.

9. The chamber of claim 8, wherein the bore angle of each outlet hole has a radial and a tangential component that provides circular flow.

10. An apparatus for processing hard disk drive substrates, comprising:
a processing chamber having an internal volume;
an RF-biased substrate support;
an inductive field source disposed near a wall of the chamber; and
a gas nozzle disposed in a wall region of the chamber facing the substrate support, the gas nozzle having a diameter that increases in the direction that gas flows through the gas nozzle.

11. The apparatus of claim 10, wherein the gas nozzle has a convex outlet plate with a plurality of outlet holes.

12. The apparatus of claim 10, further comprising a liner lining the walls of the chamber.

13. The apparatus of claim 12, further comprising a shield disposed about the gas nozzle and extending along a wall of the chamber and spaced apart therefrom.

14. The apparatus of claim 13, wherein the chamber liner and the shield comprise a conductive, non oxidizing material.

15. The apparatus of claim 13, wherein the chamber liner and the shield each comprise a material selected from the group of silicon, anodized aluminum, and graphitic carbon.

16. The apparatus of claim 13, wherein the gas nozzle extends through the shield.

17. The apparatus of claim 13, wherein the shield is a gas distribution plate.

18. A method for processing a substrate, comprising;
disposing the substrate on a substrate support in a processing chamber; directing a process gas through a gas nozzle toward the substrate in a spreading pattern;
ionizing a first portion of the process gas by forming an inductive field in the processing chamber;
ionizing a second portion of the process gas by coupling RF power to the substrate support; and
selectively altering a magnetic property of a portion of the substrate by accelerating ions generated by the inductive field and the RF power toward the substrate.

19. The method of claim 18, further comprising cooling the substrate by providing a cooling gas to the chamber through the gas nozzle and closing a throttle valve disposed in an outlet portal of the processing chamber.

20. A cluster tool for processing a hard disk drive substrate, comprising:
a transfer chamber; and
a patterning chamber coupled to the transfer chamber, wherein the patterning chamber comprises:
a chamber wall defining an internal volume of the patterning chamber;
a substrate support disposed in the internal volume of the patterning chamber;
a cone-shaped gas nozzle disposed in a wall region of the patterning chamber facing the substrate support; and
an inductive field source disposed in a canister coupled to a wall of the patterning chamber facing the substrate support.

21. The cluster tool of claim 20, wherein the patterning chamber further comprises a gas source in fluid communication with the gas nozzle, and the gas nozzle has a convex outlet plate with a plurality of outlet holes.

22. The cluster tool of claim 20, wherein the patterning chamber further comprises a throttle valve having a gate member with a sealing surface for covering an outlet portal of the patterning chamber.
